(19) United States
(12) Patent Application Publication
(10) Pub. No.: US 2026/0255787 A1
(43) Pub. Date: Aug. 27, 2026

(54) QUANTUM DOT LIGHT EMITTING DEVICE COMPRISING INORGANIC ELECTRON TRANSPORTING LAYER AND ORGANIC ELECTRON TRANSPORTING LAYER

(71) Applicants: Beijing BOE Technology Development Co., Ltd., Beijing (CN); BOE Technology Group Co., Ltd., Beijing (CN)

(72) Inventors: Zhigao Lu, Beijing (CN); Haowei Wang, Beijing (CN); Xiaoyuan Zhang, Beijing (CN); Zhuo Chen, Beijing (CN)

(73) Assignees: Beijing BOE Technology Development Co., Ltd., Beijing (CN); BOE Technology Group Co., Ltd., Beijing (CN)

(21) Appl. No.: 19/645,836

(22) Filed: Apr. 13, 2026

Related U.S. Application Data
(63) Continuation of application No. 17/922,821, filed on Dec. 29, 2021.

(51) Int. Cl. H10K 50/16; H10K 50/115; H10K 71/20; H10K 101/30; H10K 102/00

(52) U.S. Cl. CPC H10K 50/166; H10K 50/115; H10K 71/233; H10K 2101/30; H10K 2102/351

(57) ABSTRACT

A light emitting device and a producing method thereof, and a display device. The light emitting device includes: a plurality of light emitting areas that are arranged in an array, and non-light emitting areas between neighboring light emitting areas; the light emitting device includes an inorganic electron transporting layer, an organic electron transporting layer and a quantum-dot layer that are arranged sequentially in layer configuration, the inorganic electron transporting layer is located within the light emitting areas and the non-light emitting areas, and the organic electron transporting layer and the quantum-dot layer are located within the light emitting areas; and an absolute value of a difference between an energy value of a lowest unoccupied molecular orbital of the inorganic electron transporting layer and an energy value of a lowest unoccupied molecular orbital of the organic electron transporting layer is less than or equal to a preset value.

### CROSS REFERENCE TO RELEVANT APPLICATIONS

This is a continuation application of U.S. application Ser. No. 17/922,821, filed on Nov. 2, 2022, which is a national stage application filed under 35 USC 371 of International Application No. PCT/CN2021/142481, filed Dec. 29, 2021, the disclosure of which is hereby incorporated in its entirety by reference.

### TECHNICAL FIELD

The present application relates to the technical field of displaying and, more particularly, to a light emitting device and a producing method thereof, and a display device.

### BACKGROUND

As compared with Organic Light Emitting Diode (OLED) displays, Quantum-Dot Light Emitting Diode (QLED) displays have the advantages such as a narrower light-emission peak, a higher color saturation and a wider color gamut. With the deep development of the technology of quantum dot, the study on QLED displays is increasingly more sophisticated, and the quantum efficiency is continuously increasing. However, in conventional quantum-dot patterning processes, residue very easily happens after the development, which results in the problem of color mixing in the full-color quantum-dot displaying, thereby deteriorating the displaying quality.

### SUMMARY

The embodiments of the present application employ the following technical solutions:

In an aspect, there is provided a light emitting device, wherein the light emitting device comprises: a plurality of light emitting areas that are arranged in an array, and non-light emitting areas between neighboring light emitting areas;
the light emitting device comprises an inorganic electron transporting layer, an organic electron transporting layer and a quantum-dot layer that are arranged sequentially in layer configuration, the inorganic electron transporting layer is located within the light emitting areas and the non-light emitting areas, and the organic electron transporting layer and the quantum-dot layer are located within the light emitting areas; and
an absolute value of a difference between an energy value of a lowest unoccupied molecular orbital of the inorganic electron transporting layer and an energy value of a lowest unoccupied molecular orbital of the organic electron transporting layer is less than or equal to a preset value.

Optionally, the preset value comprises 0.1 eV-0.4 eV.

Optionally, a thickness of the organic electron transporting layer and a thickness of the inorganic electron transporting layer are unequal.

Optionally, the thicknesses of the organic electron transporting layer is less than the thickness of the inorganic electron transporting layer.

Optionally, an interface roughness of the organic electron transporting layer is greater than or equal to an interface roughness of the inorganic electron transporting layer.

Optionally, an electron transport rate of the organic electron transporting layer is less than an electron transport rate of the inorganic electron transporting layer.

Optionally, the light emitting areas comprise a first light emitting area and a second light emitting area, and thicknesses of the organic electron transporting layers within the first light emitting area and the second light emitting area are unequal.

Optionally, the light emitting areas further comprise a third light emitting area, and a thickness of the organic electron transporting layer within the third light emitting area is unequal to a thickness of the organic electron transporting layer within at least one of the first light emitting area and the second light emitting area.

Optionally, a material of the organic electron transporting layer comprises HATCN, BPhen or BCP.

Optionally, the light emitting device further comprises a substrate, and the inorganic electron transporting layer is disposed on the substrate; and
a thickness of the organic electron transporting layer in a direction perpendicular to the substrate is 0.5-60 nm.

Optionally, a material of the inorganic electron transporting layer includes any one or more of zinc oxide, zirconium oxide, aluminium oxide, magnesium zinc oxide and magnesium sodium oxide.

Optionally, each of the light emitting areas further comprises a cathode, and a hole transporting layer, a hole injection layer and an anode that are arranged sequentially in layer configuration on the quantum-dot layer;
wherein the cathode is disposed on one side of the inorganic electron transporting layer that is away from the organic electron transporting layer.

In another aspect, there is provided a display device, wherein the display device comprises the light emitting device according to the first aspect.

In yet another aspect, there is provided a producing method of a light emitting device, wherein the light emitting device comprises: a plurality of light emitting areas that are arranged in an array, and non-light emitting areas between neighboring light emitting areas;
the light emitting device comprises an inorganic electron transporting layer, an organic electron transporting layer and a quantum-dot layer that are arranged sequentially in layer configuration; and
an absolute value of a difference between an energy value of a lowest unoccupied molecular orbital of the inorganic electron transporting layer and an energy value of a lowest unoccupied molecular orbital of the organic electron transporting layer is less than or equal to a preset value;
wherein the producing method comprises:

using the organic electron transporting layer as a sacrificial layer for patterning and photoetching of the quantum-dot layer.

Optionally, the step of forming, within the light emitting areas, the inorganic electron transporting layers, the organic electron transporting layers and the quantum-dot layers that are arranged sequentially in layer configuration comprises:

forming the inorganic electron transporting layers at least within the light emitting areas;
forming, on the inorganic electron transporting layers, an organic electron-transportation thin film that covers the light emitting areas and the non-light emitting areas;
forming a photoetching thin film covering the organic electron-transportation thin film, wherein an entirety formed by the photoetching thin film and the organic electron-transportation thin film comprises a plurality of first to-be-removed areas that are arranged in an array, and second to-be-removed areas located between neighboring first to-be-removed areas; and the first to-be-removed areas correspond to the light emitting areas, and the second to-be-removed areas correspond to the non-light emitting areas;
removing the photoetching thin film and a part of the organic electron-transportation thin film that are located within the first to-be-removed areas, wherein a residual part of the organic electron-transportation thin film within the first to-be-removed areas forms the organic electron transporting layers;
forming a quantum-dot thin film that covers the organic electron transporting layers and the photoetching thin film that is located within the second to-be-removed areas; and
removing the photoetching thin film and the organic electron-transportation thin film that are located within the second to-be-removed areas, and the quantum-dot thin film covering the second to-be-removed areas, wherein the quantum-dot thin film covering the organic electron transporting layers located within the first to-be-removed areas forms the quantum-dot layers.

Optionally, the step of removing the photoetching thin film and the part of the organic electron-transportation thin film that are located within the first to-be-removed areas comprises:
performing sequentially exposing, developing and etching to the first to-be-removed areas, to remove the photoetching thin film and the part of the organic electron-transportation thin film that are located within the first to-be-removed areas.

Optionally, the step of removing the photoetching thin film and the organic electron-transportation thin film that are located within the second to-be-removed areas, and the quantum-dot thin film covering the second to-be-removed areas comprises:
by using a good solvent of the organic electron-transportation thin film, stripping the photoetching thin film and the organic electron-transportation thin film that are located within the second to-be-removed areas, and the quantum-dot thin film covering the second to-be-removed areas.

Optionally, the step of forming the photoetching thin film covering the organic electron-transportation thin film comprises:
by spin coating, forming the photoetching thin film covering the organic electron-transportation thin film.

Optionally, the step of forming, within the light emitting areas, the inorganic electron transporting layers, the organic electron transporting layers and the quantum-dot layers that are arranged sequentially in layer configuration comprises:
forming the inorganic electron transporting layers at least within the light emitting areas;
forming, on the inorganic electron transporting layers, an organic electron-transportation thin film that covers the light emitting areas and the non-light emitting areas;
forming a quantum-dot thin film covering the organic electron-transportation thin film, wherein the quantum-dot thin film comprises reservation areas and removal areas, the reservation areas correspond to the light emitting areas, and the removal areas correspond to the non-light emitting areas;
removing the quantum-dot thin film located within the removal areas; and
removing the residual quantum-dot thin film located within the removal areas, and the organic electron-transportation thin film corresponding to the removal areas, wherein a part of the organic electron-transportation thin film that corresponds to the reservation areas forms the organic electron transporting layers, and the quantum-dot thin film within the reservation areas forms the quantum-dot layers.

In still another aspect, there is provided a producing method of a light emitting device, wherein the light emitting device comprises: a plurality of light emitting areas that are arranged in an array, and non-light emitting areas between neighboring light emitting areas;
the light emitting device comprises an inorganic electron transporting layer, an organic electron transporting layer and a quantum-dot layer that are arranged sequentially in layer configuration; and
an absolute value of a difference between an energy value of a lowest unoccupied molecular orbital of the inorganic electron transporting layer and an energy value of a lowest unoccupied molecular orbital of the organic electron transporting layer is less than or equal to a preset value;
wherein the producing method comprises:
forming the inorganic electron transporting layers within the light emitting areas and the non-light emitting areas, and forming the organic electron transporting layers and the quantum-dot layers within the light emitting areas.

The above description is merely a summary of the technical solutions of the present application. In order to more clearly know the elements of the present application to enable the implementation according to the contents of the description, and in order to make the above and other purposes, features and advantages of the present application more apparent and understandable, the specific embodiments of the present application are provided below.

### BRIEF DESCRIPTION OF THE DRAWINGS

In order to illustrate the technical solutions of the embodiments of the present application or the prior art more clearly, the figures that are required to describe the embodiments or the prior art will be briefly described below. Apparently, the figures that are described below are embodiments of the present application, and a person skilled in the art may obtain other figures according to these figures without paying creative work.

FIG. 1 schematically shows a schematic structural diagram of a light emitting device;

FIG. 2 schematically shows a schematic structural diagram of another light emitting device;

In FIG. 3, FIG. a is a photoluminescence diagram of a quantum-dot base plate a, FIG. b is a photoluminescence diagram of the base plate after it has been washed 1 time, and FIG. c is a photoluminescence diagram of the base plate after it has been washed 4 times;

In FIG. 4, FIG. al is a photoluminescence diagram of a quantum-dot base plate b, FIG. b1 is a photoluminescence diagram of the base plate after it has been washed 1 time, and FIG. c1 is a photoluminescence diagram of the base plate after it has been washed 4 times;

FIG. 5 schematically shows schematic diagrams of a flow of producing a light emitting device;

FIG. 6 schematically shows schematic diagrams of another flow of producing a light emitting device; and

FIG. 7 schematically shows a schematic structural diagram of a first light emitting area, a second light emitting area and a third light emitting area.

### DETAILED DESCRIPTION

In order to make the objects, the technical solutions and the advantages of the embodiments of the present application clearer, the technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In the embodiments of the present application, terms such as “first” and “second” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features. Moreover, the meaning of “plurality of” is “two or more”, unless explicitly and particularly defined otherwise.

In the drawings, in order for clarity, the thicknesses of the layers, the films, the panels, the areas and so on are exaggerated. The exemplary embodiments are described with reference to the cross-sectional views of the schematic diagrams as idealized embodiments herein. Accordingly, deviations from the shapes of the figures as the result of, for example, producing techniques and/or tolerances may be predicted. Therefore, the embodiments described herein should not be interpreted as limited to the specific shapes of the areas shown herein, but should include the deviations in terms of the shapes caused by, for example, production. For example, an area illustrated or described as flat may typically have a rough and/or nonlinear feature. Moreover, an illustrated sharp angle may be rounded. Therefore, the areas shown in the drawings are essentially illustrative, and their shapes are not intended to illustrate the accurate shapes of the areas, and are not intended to limit the scopes of the claims.

As used herein, the term “and/or” includes any one of and all of the combinations of one or more of the related listed items. As can be further understood, the term “include” or “comprise”, when used in this specification, indicates the existence of the stated feature, area, entirety, step, operation, element and/or component, but does not exclude the existence or addition of one or more other features, areas, entireties, steps, operations, elements, components and/or combinations thereof.

In the related art, in the patterning of the quantum-dot layer, because of the interaction between the quantum dot and the base plate and so on, there will be remaining of the quantum dot within the non-patterning areas, and such residual quantum dot is very difficult to remove, which results in color mixing in the finally formed device, thereby highly deteriorating the performance of the device. Conventional solutions include the following. In the first method, the residual quantum dot is removed by a fierce means (for example, sonication). However, the quantum dots within the areas that have already been patterned might also fall or be destroyed during the sonication, which affects the normal light emission. In the second method, the residue is reduced by changing the complex of the quantum dot. However, currently it is very difficult to select the complex. In the third method, a method of indirect patterning is used, by introducing a sacrificial layer. However, in such a method, the sacrificial layer has a very small amount of residue on the lower film layer, and the residue is caused by the intermolecular force, and is substantially very difficult to remove. Moreover, the residue highly affects the performance of the device, and at the same time results in the problems of a low efficiency and a poor morphology of the film layer.

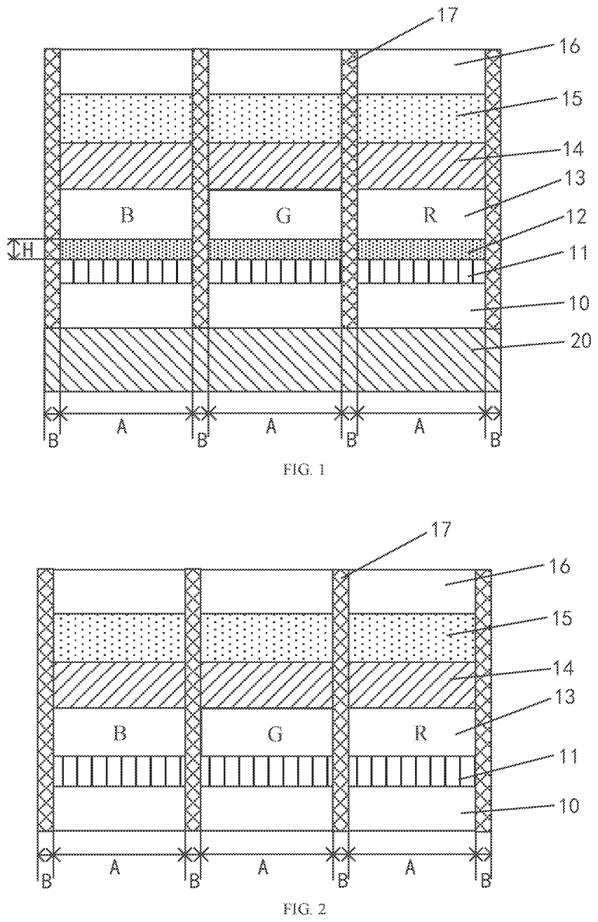

Based on the above, an embodiment of the present application provides a light emitting device. Referring to FIG. 1, the light emitting device includes: a plurality of light emitting areas A that are arranged in an array, and non-light emitting areas B between the neighboring light emitting areas A.

Each of the light emitting areas A includes an inorganic electron transporting layer 11, an organic electron transporting layer 12 and a quantum-dot layer 13 that are arranged sequentially in layer configuration. The absolute value of the difference between the energy value of the lowest unoccupied molecular orbital of the inorganic electron transporting layer and the energy value of the lowest unoccupied molecular orbital of the organic electron transporting layer is less than or equal to a preset value.

The above-described lowest unoccupied molecular orbital (LUMO) refers to, among the molecular orbitals not occupied by an electron, the molecular orbital that has the lowest energy. The energy value of the lowest unoccupied molecular orbital is also referred to as the LUMO value. In the following, the lowest unoccupied molecular orbital (“LUMO”) energy level is represented by the absolute value from vacuum. Furthermore, when the LUMO energy level is described as “deep”, “high” or “large”, the LUMO energy level has a large absolute value as compared with “0 eV”, i.e., the vacuum energy level, while when the LUMO energy level is described as “shallow”, “low” or “small”, the LUMO energy level has a small absolute value as compared with “0 eV”, i.e., the vacuum energy level. If the absolute value of the difference between the LUMO value of the inorganic electron transporting layer and the LUMO value of the organic electron transporting layer is lower (less than or equal to the preset value), electrons more easily pass through the inorganic electron transporting layer, to enter the quantum-dot layer, in which case the influence on the light-emission performance by the organic electron transporting layer is substantially negligible. The specific value of the preset value is not limited herein, as long as it is satisfied that the organic electron transporting layer does not affect the light-emission performance. As an example, the preset value may be 0.4 ev, and in this case, the absolute value of the difference between the LUMO value of the inorganic electron transporting layer and the LUMO value of the organic electron transporting layer may be 0.1 eV, 0.2 eV, 0.3 eV, 0.4 eV and so on, and is not listed one by one herein.

The specific materials of the inorganic electron transporting layer and the organic electron transporting layer are not limited, as long as it is satisfied that the absolute value of the difference between the LUMO value of the inorganic electron transporting layer and the LUMO value of the organic electron transporting layer is less than or equal to the preset value. The LUMO value of the inorganic electron transporting layer may be greater than the LUMO value of the organic electron transporting layer, or the LUMO value of the inorganic electron transporting layer may be less than the LUMO value of the organic electron transporting layer, which is not limited herein. The specific LUMO values of the inorganic electron transporting layer and the organic electron transporting layer are not limited herein either. As an example, the LUMO value of the inorganic electron transporting layer may be −5 eV to −3.5 eV, for example, −5 eV, −4.2 eV and −3.5 eV, and the LUMO value of the organic electron transporting layer may be −5.4 eV to −3.1 eV, for example, −5.4 eV, −4.0 eV and −3.1 eV.

In the quantum-dot layer, the specific structure of the quantum dot is not limited. As an example, the quantum dot may include a core-shell structure. The core of the quantum dot QD may be selected from a compound of the groups II-VI, a compound of the groups III-V, a compound of the groups IV-VI, an element in the group IV, a compound of the group IV, and a combination thereof. The compound of the groups II-VI may be selected from: a binary compound, wherein the binary compound is selected from CdSe, CdTe, ZnS, ZnSe, ZnTe, ZnO, HgS, HgSe, HgTe, MgSe, MgS and a mixture thereof, a ternary compound, wherein the ternary compound is selected from AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof, and a quaternary compound, wherein the quaternary compound is selected from HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof. The compound of the groups III-V may be selected from: a binary compound, wherein the binary compound is selected from GaN, GaP, GaAs, GaSb, AlN, AlP, AlAs, AlSb, InN, InP, InAs, InSb and a mixture thereof, a ternary compound, wherein the ternary compound is selected from GaNP, GaNAs, GaNSb, GaPAs, GaPSb, AlNP, AlNAs, AlNSb, AlPAs, AlPSb, InGaP, InNP, InNAs, InNSb, InPAs, InPSb and a mixture thereof, and a quaternary compound, wherein the quaternary compound is selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and a mixture thereof. The compound of the groups IV-VI may be selected from: a binary compound, wherein the binary compound is selected from SnS, SnSe, SnTe, PbS, PbSe, PbTe and a mixture thereof, a ternary compound, wherein the ternary compound is selected from SnSeS, SnSeTe, SnSTe, PbSeS, PbSeTe, PbSTe, SnPbS, SnPbSe, SnPbTe and a mixture thereof, and a quaternary compound, wherein the quaternary compound is selected from SnPbSSe, SnPbSeTe, SnPbSTe and a mixture thereof. The element in the group IV may be selected from Si, Ge and a mixture thereof. The compound of the group IV may be a binary compound selected from SiC, SiGe and a mixture thereof. In one or more embodiments, the binary compound, the ternary compound and/or the quaternary compound may exist in the particle with even concentrations, or may exist in the same one particle with locally different concentration distributions.

Furthermore, a core-shell structure in which one quantum dot encircles another quantum dot may be feasible. The interface between the core and the shell may have a concentration gradient, wherein the concentration of the element existing in the shell decreases toward the center. In some embodiments, the quantum dot QD may be of a core-shell structure, wherein the core-shell structure includes a core containing a nanocrystal and a shell encircling the core. The shell of the quantum dot QD of the core-shell structure may serve as a protecting layer used to prevent or reduce the chemical deformation of the core to maintain the semiconductor property, and/or a charging layer used to provide the property of electrophoresis to the quantum dot QD. The shell may have a single layer or multiple layers. The interface between the core and the shell may have a concentration gradient, wherein the concentration of the element existing in the shell decreases toward the center. The examples of the shell of the quantum dot QD of the core-shell structure may include a metal, a nonmetallic oxide, a semiconductor compound and a combination thereof. For example, the metal and the nonmetallic oxide may independently include a binary compound (for example, SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO) and/or a ternary compound (for example, MgAl₂O₄, CoFe₂O₄, NiFe₂O₄ and/or CoMn₂O₄), but the embodiments of the present disclosure are not limited thereto. In one or more embodiments, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb and so on, but the embodiments of the present disclosure are not limited thereto.

The quantum dot QD may have a full width at half maximum (FWHM) of the spectrum of the emission wavelength of approximately 45 nm or below 45 nm, for example, approximately 40 nm or below 40 nm, and, in some embodiments, approximately 30 nm or below 30 nm. That range may improve the color, the purity and/or the color reproducibility. Furthermore, the lights emitted by such a type of the quantum dot QD are emitted in all directions, and may improve the light visual angle.

The shape of the quantum dot QD may be any suitable shape, and is not particularly limited. For example, the quantum dot QD may be a nanoparticle with a shape of a spherical, conical, multi-arm and/or cubic, a nanotube, a nanowire, a nanofiber, a nanoplate and so on.

The quantum dot QD may control the color of the emitted lights according to the average diameter of the particles, and, therefore, the quantum dot QD may have various emission colors, for example, blue, red and/or green. With the decreasing of the average diameter of the particles of the quantum dot QD, the lights in the short wavelength area may be emitted. For example, the average diameter of the quantum dot emitting a green-color light may be less than the average diameter of the quantum dot emitting a red-color light. Furthermore, the average diameter of the quantum dot emitting a blue-color light may be less than the average diameter of the quantum dot emitting a green-color light. In the present disclosure, the average diameter may refer to the arithmetic average of the diameters of a plurality of quantum-dot particles. For example, the diameter of a quantum-dot particle may refer to the average value of the widths in the cross-sections of the quantum-dot particle.

The light emitting device may include merely a quantum-dot layer of a single emitted-light color, for example, a red-color quantum-dot layer, a green-color quantum-dot layer or a blue-color quantum-dot layer, in which case the light emitting device may be used for the displaying of a single color. Alternatively, the light emitting device may also include all of the red-color quantum-dot layer R, the green-color quantum-dot layer G and the blue-color quantum-dot layer B shown in FIG. 1, in which case the light emitting device may be used for color displaying.

Referring to FIG. 1, each of the light emitting areas A may further include a cathode 10, and a hole transporting layer 14, a hole injection layer 15 and an anode 16 that are arranged sequentially in layer configuration on the quantum-dot layer 13. The cathode 10 is disposed on one side of the inorganic electron transporting layer 11 that is away from the organic electron transporting layer 12. The light emitting device is of an inversely placed type, and the sequence of its production is sequentially forming the cathode, the inorganic electron transporting layer, the organic electron transporting layer, the quantum-dot layer, the hole transporting layer, the hole injection layer and the anode. Certainly, the light emitting area may further include other film layers, to increase the luminous efficiency, which may particularly refer to the related art, and is not discussed herein further.

Referring to FIG. 1, each of the non-light emitting areas B may include a sub-pixel defining component 17, openings are disposed between the neighboring sub-pixel defining components, and the inorganic electron transporting layer, the organic electron transporting layer and the quantum-dot layer may be arranged in the opening. It should be noted that FIG. 1 merely schematically illustrates the sub-pixel defining components within the non-light emitting areas, and the cross-section of the sub-pixel defining components may be an upright trapezoid, an inversed trapezoid, a rectangle shown in FIG. 1, and so on, which is not limited herein.

Moreover, the light emitting device may further include a display panel, and the quantum-dot layer may also form a color-film layer, thereby cooperating with the display panel to realize photoluminescence. Alternatively, the quantum-dot layer may also form a backlight source, to provide a backlight to the display panel.

The inventor has found by studying that, when the organic electron transporting layer is disposed between the inorganic electron transporting layer and the quantum-dot layer, and the absolute value of the difference between the energy values of the inorganic electron transporting layer and the organic electron transporting layer is less than or equal to the preset value, by using a good solvent of the organic electron transporting layer, the organic electron transporting layer and the quantum-dot layer on the organic electron transporting layer are very easily removed thoroughly.

Two specific examples will be provided below as evidence.

In the first example, a layer of the organic electron-transportation thin film is evaporated within an area A (within the area of the white-line dotted block in FIG. a in FIG. 3) of a clean glass base plate, wherein the thickness ranges 2-60 nm. Subsequently, a quantum-dot thin film is spin-coated, wherein the quantum-dot thin film covers the glass base plate and the organic electron-transportation thin film, and has a thickness range of 10-60 nm, thereby forming a quantum-dot base plate a, wherein a photoluminescence diagram of the quantum-dot base plate a is shown in FIG. a in FIG. 3. Subsequently, the base plate shown in FIG. a in FIG. 3 is washed by using a good solvent of the organic electron-transportation thin film 5-10 times, 1 ml for one time. FIG. b in FIG. 3 is a photoluminescence diagram of the base plate after it has been washed 1 time, and FIG. c in FIG. 3 is a photoluminescence diagram of the base plate after it has been washed 4 times. By comparing the quantum-dot layers within the area A and the other areas, it be found that the quantum-dot thin film within the area A is more easily washed off than the quantum-dot thin film within the other areas. In other words, the quantum-dot thin film disposed on the organic electron-transportation thin film is more easily washed off than the quantum-dot thin film disposed on the glass base plate.

In the second example, a layer of the inorganic electron-transportation thin film is spin-coated on a clean glass base plate, wherein the thickness ranges 2-60 nm. Subsequently, a layer of the organic electron-transportation thin film is evaporated within an area A (within the area of the white-line dotted block in FIG. al in FIG. 4) and on the inorganic electron-transportation thin film, wherein the thickness range is 10-60 nm. Subsequently, a quantum-dot thin film is spin-coated, wherein the quantum-dot thin film covers the inorganic electron-transportation thin film and the organic electron-transportation thin film, and has a thickness range of 10-60 nm, thereby forming a quantum-dot base plate b, wherein a photoluminescence diagram of the quantum-dot base plate b is shown in FIG. al in FIG. 4. Subsequently, the base plate shown in FIG. al in FIG. 4 is washed by using a good solvent of the organic electron-transportation thin film 5-10 times, 1 ml for one time. FIG. b1 in FIG. 4 is a photoluminescence diagram of the base plate after it has been washed 1 time, and FIG. c1 in FIG. 4 is a photoluminescence diagram of the base plate after it has been washed 4 times. By comparing the quantum-dot thin films within the area A and the other areas, it can be found that the quantum-dot thin film within the area A is more easily washed off than the quantum-dot thin film within the other areas. In other words, the quantum-dot thin film disposed on the tandem structure formed by the inorganic electron-transportation thin film and the organic electron-transportation thin film is more easily washed off than the quantum-dot thin film disposed on the inorganic electron-transportation thin film.

In view of that, the organic electron-transportation thin film may be used as a sacrificial layer, thereby thoroughly removing the quantum-dot layer within the non-patterning area, to solve the problem of quantum-dot remaining. In addition, because the absolute value of the difference between the energy values of the inorganic electron transporting layer and the organic electron transporting layer is less than or equal to the preset value, even if the organic electron-transportation thin film remains between the inorganic electron transporting layer and the quantum-dot layer to form the organic electron transporting layer, that does not affect the light-emission performance.

In the present application, the organic electron transporting layer exists between the inorganic electron transporting layer and the quantum-dot layer, and, accordingly, in the patterning of the quantum-dot layer, the organic electron-transportation thin film may be used as a sacrificial layer, thereby thoroughly removing the quantum-dot layer within the non-patterning area, to solve the problem of quantum-dot remaining. In addition, the absolute value of the difference between the energy values of the inorganic electron transporting layer and the organic electron transporting layer is less than or equal to the preset value, whereby the influence on the light-emission performance by the organic electron transporting layer is substantially negligible, which, without deteriorating the light-emission performance, solves the problem of quantum-dot remaining, and results in a high efficiency and a good morphology of the film layers.

Optionally, in order to better reduce the influence on the light-emission performance by the organic electron transporting layer, the preset value includes 0.1 eV-0.4 eV. As an example, the preset value may be 0.2 eV, 0.3 eV or 0.4 eV. Particularly, by taking the case as an example for the description in which the preset value is 0.2 eV, the absolute value of the difference between the energy value of the lowest unoccupied molecular orbital of the inorganic electron transporting layer and the energy value of the lowest unoccupied molecular orbital of the organic electron transporting layer is less than or equal to a 0.2 eV, and, in this case, the difference between the energy value of the lowest unoccupied molecular orbital of the inorganic electron transporting layer and the energy value of the lowest unoccupied molecular orbital of the organic electron transporting layer may be 0.2 eV, 0.1 eV, −0.1 eV, −0.2 eV and so on.

Optionally, a thickness of the organic electron transporting layer and a thickness of the inorganic electron transporting layer are unequal. The thickness of the organic electron transporting layer is related to the producing process. In addition, if the thickness of the organic electron transporting layer is lower, its influence on the light-emission performance is lower. The thickness of the inorganic electron transporting layer is related to factors such as the specific structure of the light emitting device and the energy level matching.

Optionally, in order further alleviate the influence on the light-emission performance, the thicknesses of the organic electron transporting layer is less than the thickness of the inorganic electron transporting layer.

The methods of producing the inorganic electron transporting layer and the organic electron transporting layer are not limited. As an example, both of them may be produced by spin coating, in which case the interface roughnesses of them are not largely unequal. Alternatively, the inorganic electron transporting layer is produced by sputtering, and the organic electron transporting layer is produced by spin coating, in which case the interface roughness of the organic electron transporting layer is greater than or equal to the interface roughness of the inorganic electron transporting layer.

Optionally, an interface roughness of the organic electron transporting layer is greater than or equal to an interface roughness of the inorganic electron transporting layer. In this case, it may be inversely deduced that the organic electron transporting layer is produced by spin coating, and the inorganic electron transporting layer is produced by sputtering.

It should be noted that the interface roughness may be obtained based on the vertical deviation (for example, the amplitude parameter) of the roughness contour (section) measured by using cross-section images of transmission electron microscopy or scanning electron microscopy (for example, Cross-TEM or Cross-SEM imaging). The interface roughness may also be determined by atomic force microscopy (AFM). The interface roughness may be reported as the arithmetic average or the root mean square (RMS) of the roughness contours. The roughness contours may be obtained by using a commercial image analyzing computer program (for example, Image J), but are not limited thereto.

The electron transport rate is closely related to the material. Optionally, an electron transport rate of the organic electron transporting layer is less than an electron transport rate of the inorganic electron transporting layer.

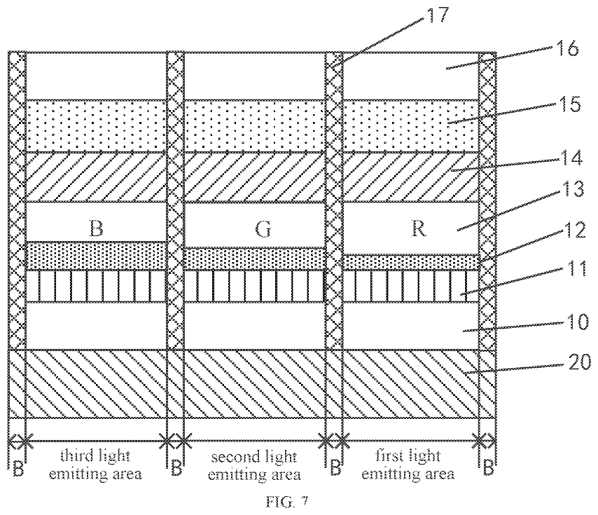

As shown in FIG. 7, optionally, the light emitting areas include a first light emitting area and a second light emitting area, and thicknesses of the organic electron transporting layers within the first light emitting area and the second light emitting area are unequal. As an example, the first light emitting area may be a red-color light emitting area, and include a red-color quantum-dot layer, and the second light emitting area may be a green-color light emitting area, and include a green-color quantum-dot layer, which are not limited herein. In the production of the light emitting device, the sequences of the production of the quantum-dot layers within the first light emitting area and the second light emitting area are different. As an example, by taking the case as an example for the description in which the first light emitting area is produced firstly and the second light emitting area is produced subsequently, after the production of the quantum-dot layer within the first light emitting area has been completed, as restricted by the process, a part of the organic electron transportation material remains within the second light emitting area, which increases the thickness of the organic electron transporting layer within the second light emitting area, and thus causes the thickness of the organic electron transporting layer within the first light emitting area to be less than the thickness of the organic electron transporting layer within the second light emitting area.

As shown in FIG. 7, optionally, the light emitting areas further include a third light emitting area, and a thickness of the organic electron transporting layer within the third light emitting area is unequal to a thickness of the organic electron transporting layer within at least one of the first light emitting area and the second light emitting area. The reason why the thickness of the organic electron transporting layer within the third light emitting area is unequal to the thickness of the organic electron transporting layer within at least one of the first light emitting area and the second light emitting area may refer to the above description that the thicknesses of the organic electron transporting layers within the first light emitting area and the second light emitting area are unequal, and is not discussed herein further. The third light emitting area may be a blue-color light emitting area. In the light emitting device, the quantum-dot layers within the first light emitting area, the second light emitting area and the third light emitting area may realize photoluminescence. As an example, the first light emitting area may be used to convert the incident light (for example, blue light) into red light, the second light emitting area may be used to convert the incident light (for example, blue light) into green light, and the third light emitting area does not change the wave band of the incident light. Alternatively, the quantum-dot layers within the first light emitting area, the second light emitting area and the third light emitting area may form a backlight source, to realize electroluminescence. As an example, the first light emitting area may emit red light, the second light emitting area may emit green light, and the third light emitting area may emit blue light.

Optionally, a material of the organic electron transporting layer includes HATCN, BPhen or BCP. The chemical structural formula of HATCN is

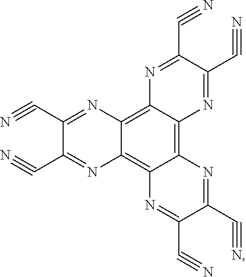 [SMILES: N#Cc1nc2c3nc(C#N)c(C#N)nc3c3nc(C#N)c(C#N)nc3c2nc1C#N]

its molecular formula is C₁₈N₁₂, and that material may also be used as a hole injection material, to form the hole injection layer. BPhen is also referred to as orthophenanthrolene, its molecular formula is C₂₄H₁₆N₂, and its chemical structural formula is

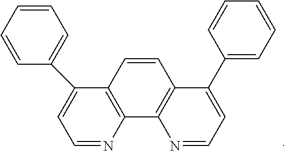 [SMILES: c1ccc(-c2ccnc3c2ccc2c(-c4ccccc4)ccnc23)cc1]

The molecular formula of BCP is C₂₆H₂₀N₂, and its chemical structural formula is

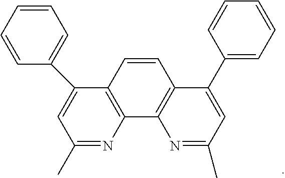 [SMILES: Cc1cc(-c2ccccc2)c2ccc3c(-c4ccccc4)cc(C)nc3c2n1]

Optionally, the material of the organic electron transporting layer may also include a derivative of PEDOT (poly(3,4-ethylidenedioxothiophene)), a derivative of PSS (poly(sulfostyrene)), a derivative of poly-N-vinylcarbazole (PVK), a derivative of polyphenylene ethenylidene, a derivative of poly-p-phenylene ethenylidene (PPV), a derivative of polymethacrylate, a derivative of poly(9,9-dioctylfluorene), a derivative of poly(spiro-fluorene), TPD (N,N′-diphenyl-N,N′-di(3-methylphenyl)-(1,1′-biphenyl)-4,4′-diamine), NPB (N,N′-di(naphth-1-yl)-N,N′-diphenyl-benzidine), m-MTDATA (tri(N-3-methylphenyl-N-phenylamino)-triphenylamine), TFB (poly(9,9-dioctylfluorene-co-N-(4-butylphenyl)diphenylamine)), PFB (poly(9,9-dioctylfluorene)-co-N,N-diphenyl-N,N-di-(p-butylphenyl)-1,4-diaminobenzene), poly-TPD or a combination thereof, but is not limited thereto.

Optionally, the light emitting device further includes a substrate 20 shown in FIG. 1, and the inorganic electron transporting layer 11 is disposed on the substrate 20. The thickness H of the organic electron transporting layer 12 in the direction perpendicular to the substrate 20 is 0.5-60 nm.

The material of the substrate is not limited. As an example, the material of the substrate may be a rigid material, for example, glass, or may be a flexible material, for example, PET (polyethylene terephthalate) and PI (polyimide).

The thickness of the organic electron transporting layer in the direction perpendicular to the substrate may be 0.5 nm, 5 nm, 10 nm, 20 nm, 30 nm, 40 nm, 50 nm, 60 nm and so on, and is not listed one by one herein. Considering that, in the production, if the thickness of the organic electron transporting layer in the direction perpendicular to the substrate is higher, more solvent is required, and the solvent influences the other film layers of the light emitting device to a certain extent, in order to reduce the influence by the solvent effect, the organic electron transporting layer of a lower thickness (for example, 0.5-30 nm) may be selected.

When the producing processes of the organic electron transporting layer are different, the formed film layers have different thickness ranges. If the organic electron transporting layer is formed by evaporating, the thickness of the organic electron transporting layer may be precisely regulated, and the formed film has a good uniformity and a good continuity, wherein the minimum thickness may reach 0.5 nm. If the organic electron transporting layer is formed by spin coating, then the minimum thickness may reach 10 nm. When the film is formed by spin coating, it is required to spin-coat the film material of a high thickness to form a continuous and uniform film layer. Therefore, the producing process may be inversely deduced by using thickness of the organic electron transporting layer in the direction perpendicular to the substrate and the size of the formed film.

Optionally, in order to reduce the process difficulty and save the cost, a material of the inorganic electron transporting layer includes any one or more of zinc oxide, zirconium oxide, aluminium oxide, magnesium zinc oxide and magnesium sodium oxide. The case in which the inorganic electron transporting layer is produced by using zinc oxide will be taken as an example below for the description.

In one or more embodiments, referring to FIG. 1, each of the light emitting areas further includes a cathode 10, and a hole transporting layer 14, a hole injection layer 15 and an anode 16 that are arranged sequentially in layer configuration on the quantum-dot layer 13. The cathode 10 is disposed on one side of the inorganic electron transporting layer 11 that is away from the organic electron transporting layer 12. Taking an inversely-placed-type light-emitting-type device as an example, the sequence of its production is sequentially forming the cathode, the inorganic electron transporting layer, the organic electron transporting layer, the quantum-dot layer, the hole transporting layer, the hole injection layer and the anode. Certainly, the light emitting area may further include other film layers, to increase the luminous efficiency, which may particularly refer to the related art, and is not discussed herein further.

An embodiment of the present application further provides a display device, wherein the display device includes the light emitting device stated above.

The display device may be a QLED display device, and may also be any products or components having a displaying function that include a QLED display device, such as a television set, a digital camera, a mobile phone and a tablet personal computer. The display device has the advantages of a high resolution and a good displaying performance.

An embodiment of the present application further includes a producing method of the light emitting device shown in FIG. 1, wherein the producing method includes:

S01: forming, within the light emitting areas, the inorganic electron transporting layers 11, the organic electron transporting layers 12 and the quantum-dot layers 13 that are arranged sequentially in layer configuration, wherein an absolute value of a difference between an energy value of a lowest unoccupied molecular orbital of the inorganic electron transporting layer and an energy value of a lowest unoccupied molecular orbital of the organic electron transporting layer is less than or equal to a preset value.

The specific methods of forming the inorganic electron transporting layers, the organic electron transporting layers and the quantum-dot layers are not limited herein. As an example, they may be produced by using processes such as spin coating, evaporating and sputtering.

It should be noted that the relevant description on the film layers in the light emitting device may refer to the above-described embodiments, and is not discussed herein further.

In the light emitting device obtained by executing the step S01, the organic electron transporting layer exists between the inorganic electron transporting layer and the quantum-dot layer, and, accordingly, in the patterning of the quantum-dot layer, the organic electron-transportation thin film may be used as a sacrificial layer, thereby thoroughly removing the quantum-dot layer within the non-patterning area, to solve the problem of quantum-dot remaining. In addition, the absolute value of the difference between the energy values of the inorganic electron transporting layer and the organic electron transporting layer is less than or equal to the preset value, whereby the influence on the light-emission performance by the organic electron transporting layer is substantially negligible, which, without deteriorating the light-emission performance, solves the problem of quantum-dot remaining, and results in a high efficiency and a good morphology of the film layers.

A particular embodiment of the step S01 will be provided below.

S01: the step of forming, within the light emitting areas, the inorganic electron transporting layers, the organic electron transporting layers and the quantum-dot layers that are arranged sequentially in layer configuration includes:

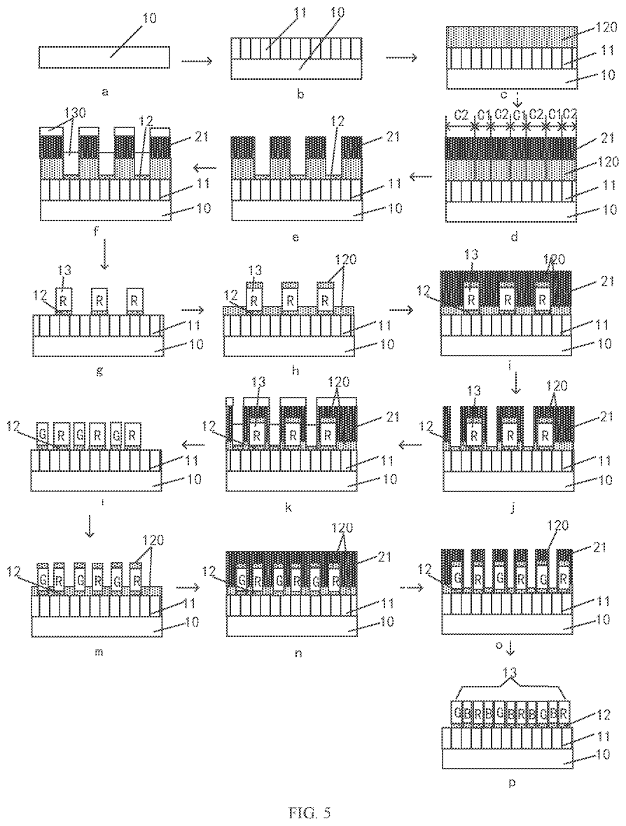

S11: referring to FIG. b in FIG. 5, forming the inorganic electron transporting layers 11 at least within the light emitting areas.

It should be noted that, in the step S11, the inorganic electron transporting layers may be disposed merely within the light emitting areas, and may also be disposed within all of the light emitting areas and the non-light emitting areas, which is not limited herein, and may be particularly determined according to practical structures. The specific method of forming the inorganic electron transporting layers is not limited herein. As an example, they may be formed by spin coating or sputtering. The thickness of the inorganic electron transporting layers ranges 5-60 nm, and their material may include zinc oxide.

Moreover, before S11 is executed, the cathodes 10 may also be firstly formed, referring to FIG. a in FIG. 5, and the inorganic electron transporting layers 11 may be formed on the cathodes 10.

S12: referring to FIG. c in FIG. 5, forming, on the inorganic electron transporting layers 11, an organic electron-transportation thin film 120 that covers the light emitting areas and the non-light emitting areas.

The specific method of forming the organic electron transporting layers is not limited herein. As an example, they may be formed by spin coating or evaporating. In order to obtain the organic electron-transportation thin film of a lower thickness, evaporating may be selected.

S13: referring to FIG. d in FIG. 5, forming a photoetching thin film 21 covering the organic electron-transportation thin film 120, wherein the entirety formed by the photoetching thin film and the organic electron-transportation thin film includes a plurality of first to-be-removed areas C1 that are arranged in an array, and second to-be-removed areas C2 located between the neighboring first to-be-removed areas C1; and the first to-be-removed areas correspond to the light emitting areas, and the second to-be-removed areas correspond to the non-light emitting areas.

The specific method of forming the photoetching thin film is not limited herein. As an example, it may be formed by spin coating. The material of the photoetching thin film is not limited herein. As an example, a material of the photoetching thin film includes photoresist.

S14: referring to FIG. e in FIG. 5, removing the photoetching thin film 21 and a part of the organic electron-transportation thin film 120 that are located within the first to-be-removed areas, wherein a residual part of the organic electron-transportation thin film within the first to-be-removed areas forms the organic electron transporting layers 12.

The specific method of removing the photoetching thin film and a part of the organic electron-transportation thin film that are located within the first to-be-removed areas is not limited herein. As an example, they may be removed by sequentially exposing, developing and etching.

It should be noted that, as limited by the current techniques, after the step S14 has been completed, the organic electron-transportation thin film located within the first to-be-removed areas cannot be removed completely, and in practice there will be some residue. If suitable material and removing process of the organic electron-transportation thin film are selected, then S14 may completely and thoroughly remove the organic electron-transportation thin film located within the first to-be-removed areas. Accordingly, in this case, in the finally formed light emitting device, there is no organic electron transporting layer between the inorganic electron transporting layers and the quantum-dot layers within the light emitting areas.

S15: referring to FIG. f in FIG. 5, forming a quantum-dot thin film 130 that covers the organic electron transporting layers and the photoetching thin film that is located within the second to-be-removed areas.

The specific method of forming the quantum-dot thin film is not limited herein. As an example, it may be formed by spin coating.

S16: removing the photoetching thin film and the organic electron-transportation thin film that are located within the second to-be-removed areas, and the quantum-dot thin film covering the second to-be-removed areas, to obtain the structure shown in FIG. g in FIG. 5, wherein the quantum-dot thin film covering the organic electron transporting layers 12 located within the first to-be-removed areas forms the quantum-dot layers 13.

The specific method of removing the photoetching thin film and a part of the organic electron-transportation thin film that are located within the second to-be-removed areas is not limited herein. As an example, they may be washed by using a good solvent of the organic electron-transportation thin film, thereby being thoroughly removed.

The above-described method of the steps S11-S16 is an indirect photoetching method, in which the organic electron-transportation thin film is used as a sacrificial layer, thereby thoroughly removing the quantum-dot layer within the non-patterning area, to solve the problem of quantum-dot remaining. In addition, the absolute value of the difference between the energy values of the inorganic electron transporting layer and the organic electron transporting layer is less than or equal to the preset value, and the influence on the light-emission performance by the organic electron transporting layer remaining between the inorganic electron transporting layer and the quantum-dot layer is substantially negligible, which, without deteriorating the light-emission performance, solves the problem of quantum-dot remaining, and results in a high efficiency and a good morphology of the film layers.

Moreover, in the light emitting device formed by executing the steps S11-S16, a small amount of the organic electron transporting layers may exist between the inorganic electron transporting layers and the quantum-dot layers within the light emitting areas, or there is no organic electron transporting layer between the inorganic electron transporting layers and the quantum-dot layers within the light emitting areas, both of which two structures of the light emitting device fall within the protection scope of the present application.

FIG. 5 illustrates by taking the case as an example in which the light emitting device includes a red-color quantum-dot layer, a green-color quantum-dot layer or a blue-color quantum-dot layer, wherein FIG. a to FIG. g are schematic diagrams of a flow of forming the red-color quantum-dot layer, FIG. h to FIG. 1 are schematic diagrams of a flow of forming the green-color quantum-dot layer, and FIG. k to FIG. p are schematic diagrams of a flow of forming the blue-color quantum-dot layer. The steps S11-S16 are described by taking the schematic diagram of the flow of the red-color quantum-dot layer as an example, and the production methods of the green-color quantum-dot layer and the blue-color quantum-dot layer are similar to that of the red-color quantum-dot layer, and are not described particularly herein. Moreover, FIG. 5 does not illustrate the specific structure of the non-light emitting areas, which may be obtained particularly by referring to the above-described producing process and the related art.

In one or more embodiments, in order to facilitate the implementation and reduce the production cost, the step S14 of removing the photoetching thin film and part of the organic electron-transportation thin film that are located within the first to-be-removed areas includes:

S141: performing sequentially exposing, developing and etching to the first to-be-removed areas, to remove the photoetching thin film and a part of the organic electron-transportation thin film that are located within the first to-be-removed areas.

In one or more embodiments, in order to facilitate the implementation and reduce the production cost, the step S16 of removing the photoetching thin film and the organic electron-transportation thin film that are located within the second to-be-removed areas, and the quantum-dot thin film covering the second to-be-removed areas includes:

S161: by using a good solvent of the organic electron-transportation thin film, stripping the photoetching thin film and the organic electron-transportation thin film that are located within the second to-be-removed areas, and the quantum-dot thin film covering the second to-be-removed areas.

The above-described good solvent of the organic electron-transportation thin film refers to that the organic electron-transportation thin film has a good solubility in that solvent, and that solvent may wash off the photoetching thin film and the organic electron-transportation thin film that are located within the second to-be-removed areas, and the quantum-dot thin film covering the second to-be-removed areas.

In one or more embodiments, in order to utilize existing producing equipment to a large extent and reduce the production cost, the step S13 of forming the photoetching thin film covering the organic electron-transportation thin film includes:

S131: by spin coating, forming the photoetching thin film covering the organic electron-transportation thin film.

Optionally, in the step S13, a material of the photoetching thin film includes photoresist. The photoresist may be a positive photoresist or a negative photoresist, which is not limited herein.

Another particular embodiment of the step S01 will be provided below.

S01: the step of forming, within the light emitting areas, the inorganic electron transporting layers, the organic electron transporting layers and the quantum-dot layers that are arranged sequentially in layer configuration includes:

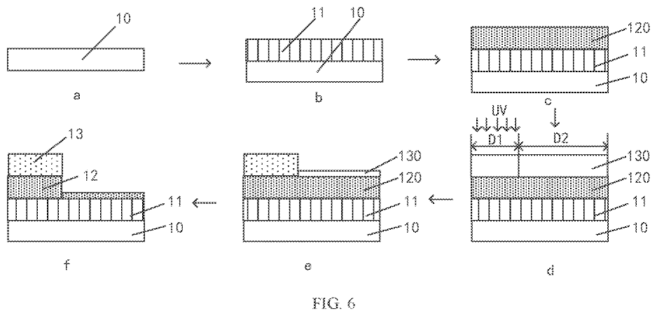

S21: referring to FIG. b in FIG. 6, forming the inorganic electron transporting layers 11 at least within the light emitting areas.

It should be noted that, in the step S21, the inorganic electron transporting layers may be disposed merely within the light emitting areas, and may also be disposed within the non-light emitting areas, which is not limited herein, and may be particularly determined according to practical structures. The specific method of forming the inorganic electron transporting layers is not limited herein. As an example, they may be formed by spin coating or sputtering. The thickness of the inorganic electron transporting layers ranges 5-60 nm, and their material may include zinc oxide.

Moreover, before S21 is executed, the cathodes 10 may also be firstly formed, referring to FIG. a in FIG. 6, and the inorganic electron transporting layers 11 may be formed on the cathodes 10.

S22: referring to FIG. c in FIG. 6, forming, on the inorganic electron transporting layers 11, an organic electron-transportation thin film 120 that covers the light emitting areas and the non-light emitting areas.

The specific method of forming the organic electron transporting layers is not limited herein. As an example, they may be formed by spin coating or evaporating. In order to obtain the organic electron transporting layers of a lower thickness, evaporating may be selected.

S23: referring to FIG. d in FIG. 6, forming a quantum-dot thin film 130 covering the organic electron-transportation thin film 120, wherein the quantum-dot thin film includes reservation areas D1 and removal areas D2, the reservation areas correspond to the light emitting areas, and the removal areas correspond to the non-light emitting areas.

The specific method of forming the quantum-dot thin film is not limited herein. As an example, it may be formed by spin coating.

S24: removing the quantum-dot thin film located within the removal areas, to obtain the structure shown in FIG. e in FIG. 6.

The specific method of removing the quantum-dot thin film is not limited herein. As an example, the method may include firstly irradiating the quantum-dot thin film located within the reservation areas by using ultraviolet light (UV), and subsequently washing by using a good solvent of the quantum-dot thin film, and accordingly the quantum-dot thin film not irradiated by the ultraviolet light (i.e., the quantum-dot thin film located within the removal areas) may be removed. By using such a method, the reason why the quantum-dot thin film located within the reservation areas is not washed off by the good solvent are as follows. In an aspect, the quantum-dot thin film located within the reservation areas, after ultraviolet-irradiated, has a cross-linking reaction itself, to form a net-like cross-linked structure, which the good solvent of the quantum-dot thin film is very difficult to enter, and therefore it is not washed off. In another aspect, after the quantum-dot thin film located within the reservation areas has been ultraviolet-irradiated, at the interface between the quantum-dot thin film and the organic electron-transportation thin film, the complexes of the quantum dot cross-links with the groups at the surface of the organic electron-transportation thin film, whereby the quantum-dot thin film located within the reservation areas closely join to the underneath organic electron-transportation thin film, and is not easily washed off.

S25: removing the residual quantum-dot thin film located within the removal areas, and the organic electron-transportation thin film corresponding to the removal areas, to obtain the structure shown in FIG. f in FIG. 6, wherein a part of the organic electron-transportation thin film that corresponds to the reservation areas forms the organic electron transporting layers 12, and the quantum-dot thin film within the reservation areas forms the quantum-dot layers 13.

It should be noted that, in the practical process, after the step S24 has been completed, the quantum-dot thin film located within the removal areas cannot be removed completely. Therefore, in the step S25, it is required to further remove the residual quantum-dot thin film within the removal areas, whereby preventing the problem of quantum-dot remaining.

The specific method of removing the residual quantum-dot thin film located within the removal areas and the organic electron-transportation thin film corresponding to the removal areas is not limited herein. As an example, they may be washed by using a good solvent of the organic electron-transportation thin film.

The method of the steps S21-S25 is a direct photoetching method, and the method has fewer process steps. It should be noted that, in the light emitting device formed by executing the steps S21-S25, the organic electron transporting layers definitely exist between the inorganic electron transporting layers and the quantum-dot layers within the light emitting areas.

FIG. 6 illustrates by taking the case of the formation of the red-color quantum-dot layer as an example, and the production methods of the green-color quantum-dot layer and the blue-color quantum-dot layer are similar to that of the red-color quantum-dot layer, and are not described particularly herein.

In one or more embodiments, in order to facilitate the implementation, the step S24 of removing the quantum-dot thin film located within the removal areas includes:

S241: by using a mask, exposing the reservation areas, to cause the quantum-dot thin film within the reservation areas to have a cross-linking reaction.

Here, the exposing light ray may be an ultraviolet ray. The quantum-dot thin film located within the reservation areas, after ultraviolet-irradiated, has a cross-linking reaction itself, to form a net-like cross-linked structure. In addition, at the interface between the quantum-dot thin film and the organic electron-transportation thin film, the complexes of the quantum dot cross-links with the groups at the surface of the organic electron-transportation thin film, whereby the quantum-dot thin film located within the reservation areas closely join to the underneath organic electron-transportation thin film.

S242: by using a good solvent of the quantum-dot thin film, washing away the quantum-dot thin film within the removal areas.

The quantum-dot thin film located within the reservation areas is not washed off, and the quantum-dot thin film located within the removal areas that is not irradiated by the ultraviolet light is washed off. However, as limited by the current techniques, the quantum-dot thin film located within the removal areas cannot be completely and thoroughly washed, and it is required to further remove the residual quantum-dot thin film within the removal areas, whereby preventing the problem of quantum-dot remaining.

In one or more embodiments, in order to effectively remove the residual quantum-dot thin film and reduce the difficulty in implementation, the step S25 of removing the residual quantum-dot thin film located within the removal areas, and the organic electron-transportation thin film corresponding to the removal areas includes:
by using a good solvent of the organic electron-transportation thin film, stripping the residual quantum-dot thin film located within the removal areas, and the organic electron-transportation thin film corresponding to the removal areas.

The above embodiments describe in detail that the quantum-dot thin film disposed on the organic electron-transportation thin film may be easily removed thoroughly, which is not discussed herein further.

In some embodiments, in order to facilitate the implementation and reduce the difficulty in production, the steps S12 and S22, i.e., the step of forming, on the inorganic electron transporting layers, the organic electron-transportation thin film that covers the light emitting areas and the non-light emitting areas includes:

by evaporating or spin coating, forming, on the inorganic electron transporting layers, the organic electron-transportation thin film that covers the light emitting areas and the non-light emitting areas.

In order to obtain the organic electron-transportation thin film of a lower thickness, evaporating may be selected.

In some embodiments, in order to facilitate the implementation and reduce the difficulty in production, the steps S11 and S21, i.e., the step of forming the inorganic electron transporting layers at least within the light emitting areas includes:
by spin coating or sputtering, forming an inorganic electron-transportation thin film located within the light emitting areas and the non-light emitting areas, wherein the inorganic electron-transportation thin film located within the light emitting areas forms the inorganic electron transporting layers.

In some embodiments, in order to form patterned inorganic electron transporting layers, the steps S11 and S21, i.e., the step of forming the inorganic electron transporting layers at least within the light emitting areas includes:
by ink-jet printing, forming the inorganic electron transporting layers located within the light emitting areas.

In some embodiments, before the step S01 of forming, within the light emitting areas, the inorganic electron transporting layers, the organic electron transporting layers and the quantum-dot layers that are arranged sequentially in layer configuration, the producing method of the light emitting device further includes:

S02: forming the cathodes at least within the light emitting areas.

In this case, the steps S11 and S21, i.e., the step of forming the inorganic electron transporting layers at least within the light emitting areas includes:

at least within the light emitting areas, and on the cathodes, forming the inorganic electron transporting layers.

Certainly, the producing method of the light emitting device further includes forming other film layers (for example, hole transporting layers, hole injection layers and anodes) on the quantum-dot layers, which may refer to the related art, and is not described in detail herein.

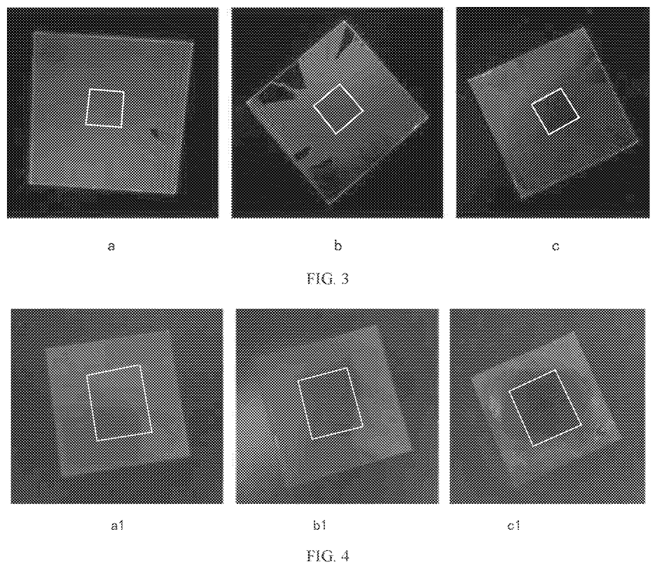

An embodiment of the present application further includes a light emitting device shown in FIG. 2, wherein the light emitting device may be produced by using the following steps:

S31: forming the inorganic electron transporting layers at least within the light emitting areas.

It should be noted that, in the step S31, the inorganic electron transporting layers may be disposed merely within the light emitting areas, and may also be disposed within all of the light emitting areas and the non-light emitting areas, which is not limited herein, and may be particularly determined according to practical structures. The specific method of forming the inorganic electron transporting layers is not limited herein. As an example, they may be formed by spin coating or sputtering. The thickness of the inorganic electron transporting layers ranges 5-60 nm, and their material may include zinc oxide.

Moreover, before S31 is executed, the cathodes may also be firstly formed, and the inorganic electron transporting layers may be formed on the cathodes.

S32: forming, on the inorganic electron transporting layers, an organic electron-transportation thin film that covers the light emitting areas and the non-light emitting areas.

The specific method of forming the organic electron transporting layers is not limited herein. As an example, they may be formed by spin coating or evaporating. In order to obtain the organic electron-transportation thin film of a lower thickness, evaporating may be selected.

An absolute value of a difference between an energy value of a lowest unoccupied molecular orbital of the inorganic electron transporting layer and an energy value of a lowest unoccupied molecular orbital of the organic electron transporting layer is less than or equal to a preset value.

S33: forming a photoetching thin film covering the organic electron-transportation thin film, wherein an entirety formed by the photoetching thin film and the organic electron-transportation thin film includes a plurality of first to-be-removed areas that are arranged in an array, and second to-be-removed areas located between neighboring first to-be-removed areas; and the first to-be-removed areas correspond to the light emitting areas, and the second to-be-removed areas correspond to the non-light emitting areas.

The specific method of forming the photoetching thin film is not limited herein. As an example, it may be formed by spin coating. The material of the photoetching thin film is not limited herein. As an example, a material of the photoetching thin film includes photoresist.

S34: removing the photoetching thin film and the whole of the organic electron-transportation thin film that are located within the first to-be-removed areas.

The specific method of removing the photoetching thin film and a part of the organic electron-transportation thin film that are located within the first to-be-removed areas is not limited herein. As an example, they may be removed by sequentially exposing, developing and etching.

It should be noted that suitable material and removing process of the organic electron-transportation thin film may be selected, to completely and thoroughly remove the organic electron-transportation thin film located within the first to-be-removed areas. Accordingly, in this case, in the finally formed light emitting device, there is no organic electron transporting layer between the inorganic electron transporting layers and the quantum-dot layers within the light emitting areas.

S35: forming a quantum-dot thin film that covers the organic electron transporting layers and the photoetching thin film that is located within the second to-be-removed areas.

The specific method of forming the quantum-dot thin film is not limited herein. As an example, it may be formed by spin coating.

S36: removing the photoetching thin film and the organic electron-transportation thin film that are located within the second to-be-removed areas, and the quantum-dot thin film covering the second to-be-removed areas, wherein the quantum-dot thin film covering the organic electron transporting layers located within the first to-be-removed areas forms the quantum-dot layers.

The specific method of removing the photoetching thin film and a part of the organic electron-transportation thin film that are located within the second to-be-removed areas is not limited herein. As an example, they may be washed by using a good solvent of the organic electron-transportation thin film, thereby being thoroughly removed.

By executing S31-S36, the light emitting device shown in FIG. 2 may be obtained, and the light emitting device includes: a plurality of light emitting areas that are arranged in an array, and non-light emitting areas between neighboring light emitting areas. Each of the light emitting areas includes an inorganic electron transporting layer and a quantum-dot layer that are arranged sequentially in layer configuration. The description on the structures of the relevant film layers in the light emitting device may refer to the above-described embodiments, and is not discussed herein further.

The “one embodiment”, “an embodiment” or “one or more embodiments” as used herein means that particular features, structures or characteristics described with reference to an embodiment are included in at least one embodiment of the present application. Moreover, it should be noted that here an example using the wording “in an embodiment” does not necessarily refer to the same one embodiment.

The description provided herein describes many concrete details. However, it can be understood that the embodiments of the present application may be implemented without those concrete details. In some of the embodiments, well-known processes, structures and techniques are not described in detail, so as not to affect the understanding of the description.

Finally, it should be noted that the above embodiments are merely intended to explain the technical solutions of the present application, and not to limit them. Although the present application is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present application.

1. A light emitting device, wherein the light emitting device comprises: a plurality of light emitting areas that are arranged in an array, and non-light emitting areas between neighboring light emitting areas;
the light emitting device comprises an inorganic electron transporting layer, an organic electron transporting layer and a quantum-dot layer that are arranged sequentially in layer configuration, the inorganic electron transporting layer is located within the light emitting areas and the non-light emitting areas, and the organic electron transporting layer and the quantum-dot layer are located within the light emitting areas; and
an absolute value of a difference between an energy value of a lowest unoccupied molecular orbital of the inorganic electron transporting layer and an energy value of a lowest unoccupied molecular orbital of the organic electron transporting layer is less than or equal to a preset value.

2. The light emitting device according to claim 1, wherein the preset value comprises 0.1 eV-0.4 eV.

3. The light emitting device according to claim 2, wherein a thickness of the organic electron transporting layer and a thickness of the inorganic electron transporting layer are unequal.

4. The light emitting device according to claim 3, wherein the thicknesses of the organic electron transporting layer is less than the thickness of the inorganic electron transporting layer.

5. The light emitting device according to claim 3, wherein an interface roughness of the organic electron transporting layer is greater than or equal to an interface roughness of the inorganic electron transporting layer.

6. The light emitting device according to claim 3, wherein an electron transport rate of the organic electron transporting layer is less than an electron transport rate of the inorganic electron transporting layer.

7. The light emitting device according to claim 1, wherein the light emitting areas comprise a first light emitting area and a second light emitting area, and thicknesses of the organic electron transporting layers within the first light emitting area and the second light emitting area are unequal.

8. The light emitting device according to claim 7, wherein the light emitting areas further comprise a third light emitting area, and a thickness of the organic electron transporting layer within the third light emitting area is unequal to a thickness of the organic electron transporting layer within at least one of the first light emitting area and the second light emitting area.

9. The light emitting device according to claim 1, wherein a material of the organic electron transporting layer comprises HATCN, BPhen or BCP.

10. The light emitting device according to claim 1, wherein the light emitting device further comprises a substrate, and the inorganic electron transporting layer is disposed on the substrate; and
a thickness of the organic electron transporting layer in a direction perpendicular to the substrate is 0.5-60 nm.

11. The light emitting device according to claim 1, wherein a material of the inorganic electron transporting layer includes any one or more of zinc oxide, zirconium oxide, aluminium oxide, magnesium zinc oxide and magnesium sodium oxide.

12. The light emitting device according to claim 1, wherein each of the light emitting areas further comprises a cathode, and a hole transporting layer, a hole injection layer and an anode that are arranged sequentially in layer configuration on the quantum-dot layer;
wherein the cathode is disposed on one side of the inorganic electron transporting layer that is away from the organic electron transporting layer.

13. A display device, wherein the display device comprises the light emitting device according to claim 1.

14. A producing method of a light emitting device, wherein the light emitting device comprises: a plurality of light emitting areas that are arranged in an array, and non-light emitting areas between neighboring light emitting areas;
the light emitting device comprises an inorganic electron transporting layer, an organic electron transporting layer and a quantum-dot layer that are arranged sequentially in layer configuration; and
an absolute value of a difference between an energy value of a lowest unoccupied molecular orbital of the inorganic electron transporting layer and an energy value of a lowest unoccupied molecular orbital of the organic electron transporting layer is less than or equal to a preset value;
wherein the producing method comprises:
using the organic electron transporting layer as a sacrificial layer for patterning and photoetching of the quantum-dot layer.

15. The producing method according to claim 14, wherein the step of forming, within the light emitting areas, the inorganic electron transporting layers, the organic electron transporting layers and the quantum-dot layers that are arranged sequentially in layer configuration comprises:
forming the inorganic electron transporting layers at least within the light emitting areas;
forming, on the inorganic electron transporting layers, an organic electron-transportation thin film that covers the light emitting areas and the non-light emitting areas;
forming a photoetching thin film covering the organic electron-transportation thin film, wherein an entirety formed by the photoetching thin film and the organic electron-transportation thin film comprises a plurality of first to-be-removed areas that are arranged in an array, and second to-be-removed areas located between neighboring first to-be-removed areas; and the first to-be-removed areas correspond to the light emitting areas, and the second to-be-removed areas correspond to the non-light emitting areas;
removing the photoetching thin film and a part of the organic electron-transportation thin film that are located within the first to-be-removed areas, wherein a residual part of the organic electron-transportation thin film within the first to-be-removed areas forms the organic electron transporting layers;
forming a quantum-dot thin film that covers the organic electron transporting layers and the photoetching thin film that is located within the second to-be-removed areas; and
removing the photoetching thin film and the organic electron-transportation thin film that are located within the second to-be-removed areas, and the quantum-dot thin film covering the second to-be-removed areas, wherein the quantum-dot thin film covering the organic electron transporting layers located within the first to-be-removed areas forms the quantum-dot layers.

16. The producing method according to claim 15, wherein the step of removing the photoetching thin film and the part of the organic electron-transportation thin film that are located within the first to-be-removed areas comprises:
performing sequentially exposing, developing and etching to the first to-be-removed areas, to remove the photoetching thin film and the part of the organic electron-transportation thin film that are located within the first to-be-removed areas.

17. The producing method according to claim 15, wherein the step of removing the photoetching thin film and the organic electron-transportation thin film that are located within the second to-be-removed areas, and the quantum-dot thin film covering the second to-be-removed areas comprises:
by using a good solvent of the organic electron-transportation thin film, stripping the photoetching thin film and the organic electron-transportation thin film that are located within the second to-be-removed areas, and the quantum-dot thin film covering the second to-be-removed areas.

18. The producing method according to claim 15, wherein the step of forming the photoetching thin film covering the organic electron-transportation thin film comprises:
by spin coating, forming the photoetching thin film covering the organic electron-transportation thin film.

19. The producing method according to claim 14, wherein the step of forming, within the light emitting areas, the inorganic electron transporting layers, the organic electron transporting layers and the quantum-dot layers that are arranged sequentially in layer configuration comprises:
forming the inorganic electron transporting layers at least within the light emitting areas;
forming, on the inorganic electron transporting layers, an organic electron-transportation thin film that covers the light emitting areas and the non-light emitting areas;
forming a quantum-dot thin film covering the organic electron-transportation thin film, wherein the quantum-dot thin film comprises reservation areas and removal areas, the reservation areas correspond to the light emitting areas, and the removal areas correspond to the non-light emitting areas;
removing the quantum-dot thin film located within the removal areas; and
removing the residual quantum-dot thin film located within the removal areas, and the organic electron-transportation thin film corresponding to the removal areas, wherein a part of the organic electron-transportation thin film that corresponds to the reservation areas forms the organic electron transporting layers, and the quantum-dot thin film within the reservation areas forms the quantum-dot layers.

20. A producing method of a light emitting device, wherein the light emitting device comprises: a plurality of light emitting areas that are arranged in an array, and non-light emitting areas between neighboring light emitting areas;
the light emitting device comprises an inorganic electron transporting layer, an organic electron transporting layer and a quantum-dot layer that are arranged sequentially in layer configuration; and
an absolute value of a difference between an energy value of a lowest unoccupied molecular orbital of the inorganic electron transporting layer and an energy value of a lowest unoccupied molecular orbital of the organic electron transporting layer is less than or equal to a preset value;
wherein the producing method comprises:
forming the inorganic electron transporting layers within the light emitting areas and the non-light emitting areas, and forming the organic electron transporting layers and the quantum-dot layers within the light emitting areas.
